(19) United States
(12) Patent Application Publication
(10) Pub. No.: US 2024/0013511 A1
(43) Pub. Date: Jan. 11, 2024

(54) Identification Data Set for Electronic Modules

(71) Applicant: Siemens Aktiengesellschaft, München (DE)

(72) Inventors: Peter Frühauf, Falkensee (DE); Rene Blank, Berlin (DE); Matthias Heimann, Potsdam (DE); Bernd Müller, Falkenberg (DE)

(73) Assignee: Siemens Aktiengesellschaft, München (DE)

(21) Appl. No.: 18/042,919

(22) PCT Filed: Aug. 12, 2021
(86) PCT No.: PCT/EP2021/072445

§ 371 Date: Feb. 24, 2023

(30) Foreign Application Priority Data
Aug. 27, 2020 (EP) 20193009.6

(51) Int. Cl. G06V 10/75; H05K 3/34; H01L 23/544; H05K 1/02; H05K 1/18; G06K 7/10; G06V 20/80

(52) U.S. Cl. CPC G06V 10/759; H05K 3/3436; H01L 23/544; H05K 1/0275; H05K 1/181; G06K 7/1099; G06V 20/80; H01L 2224/48091; H01L 2224/48245; H01L 24/48

(57) ABSTRACT

Various embodiments of the teachings herein include a computer-implemented method for generating an identification data set for an electronic module having a substrate, a joint, and an electronic component. An example method includes: providing a digital and/or X-ray recording of at least a partial region of the module; and generating the identification data set based on at least a portion of the recording, the portion including the joint. The identification data set identifies at least one of a number, an arrangement, and/or a size of gas inclusions in the joint.

### CROSS-REFERENCE TO RELATED APPLICATIONS

This application is a U.S. National Stage Application of International Application No. PCT/EP2021/072445 filed Aug. 12, 2021, which designates the United States of America, and claims priority to EP Application No. 20193009.6 filed Aug. 27, 2020, the contents of which are hereby incorporated by reference in their entirety.

### TECHNICAL FIELD

The present disclosure relates to electronic modules. Various embodiments include methods and/or systems for generating an identification data set for an electronic module, for producing an electronic module, using an identification data set, and/or checking an electronic module.

### BACKGROUND

Identification data set may be used, for example, in the manufacture of electronic products. Counterfeit products keep appearing on the market. In addition, products can be modified by third parties without authorization, which has a negative impact on the safety of the product.

Until now, the problem has been solved through trusted distribution channels. Furthermore, electronic products can be protected by so-called “trusted platform modules” (TPM) or other additional electronic components, which are protected using cryptographic methods, for example. There are also solutions based on the application of authenticity features using for example holograms, other stickers, or the like, or NanoInk, artificial DNA, etc.

### SUMMARY

The teachings of the present disclosure may be used for specifying a simplified method for generating a secure identification data set for electronic modules. For example, some embodiments include a computer-implemented method for generating an identification data set (ID100) for an electronic module (100), the module (100) having at least one substrate (110), at least one joint (115), and at least one electronic component (120), the method comprising: providing a digital and/or X-ray recording (100*) of at least a partial region of the module (100), generating the identification data set (ID100) on the basis of at least a partial region (101*) of the recording (100*), the partial region (101*) comprising one or more joints (115), wherein the identification data set (ID100) is generated on the basis of at least a number, an arrangement and/or a size of gas inclusions (116) in at least one of the joints (115).

In some embodiments, the generation of the identification data set (ID100) comprises a combination of at least two different methods for providing the recording (100*).

In some embodiments, the generation of the identification data set (ID100) comprises at least a calculation of a hash value of at least one partial region (101*) of the recording (100*).

In some embodiments, at least one serial number (SN100) of the module (100) is stored when the identification data set (ID100) is generated.

In some embodiments, the generation of the identification data set (ID100) comprises the generation of a quality value on the basis of the number and/or the arrangement and/or the size of the gas inclusions (116).

As another example, some embodiments include a method for producing an electronic module (100), comprising: providing a substrate (110) with joining material, equipping at least one electronic component (120), finishing at least one joint (120) between the electronic component (120) and the substrate (110), and generating an identification data set (ID100) according to a method as claimed in any one of the preceding claims.

As another example, some embodiments include the use of an identification data set (ID100) generated as described herein, at least as part of a cryptographic secret for authentication and/or encryption of a communication of an electronic module.

As another example, some embodiments include the use of an identification data set (ID100) generated as described herein as a physical unclonable function.

As another example, some embodiments include a method for checking an electronic module (100), comprising: providing an identification data set (ID100) as described herein for the module (100), providing a test recording of at least a partial region of the module (100), generating a test data set on the basis of at least a partial region of the test recording, and comparing the identification data set (ID100) with the test data set.

In some embodiments, the method further includes selecting the partial region of the test recording on the basis of partial region information in the identification data set (ID100).

### BRIEF DESCRIPTION OF THE DRAWINGS

The teachings herein are described and explained in more detail below on the basis of the exemplary embodiments illustrated in the figures. In the figures:

FIG. 1 shows an electronic module 100 in cross section,

FIG. 2 shows a plan view of an electronic module,

FIG. 3 shows an X-ray recording of an electronic module,

FIG. 4 shows a further X-ray recording, and

FIG. 5 schematically shows the generation of an identification data set.

### DETAILED DESCRIPTION

The teachings of the present disclosure include computer-implemented methods for generating an identification data set for an electronic module. The module has at least one substrate, at least one joint, and at least one electronic component. In some embodiments, a method comprises: providing a digital and/or X-ray recording of at least a partial region of the module, and generating the identification data set on the basis of at least a partial region of the recording, the partial region comprising one or more joints, wherein the identification data set is generated on the basis of at least a number, an arrangement and/or a size of gas inclusions in at least one of the joints.

The recording can be made and provided during the ongoing production process for the module. As a rule, automatic optical inspection machines, such as “automated optical inspection” (AO′) or “automated X-ray inspection” (AXI), already make such recordings. Thus, in order to use these recordings, they can be made available directly in the production process. In this case, the identification data set is a unique data set which is assigned to the respective electronic module and is suitable for the clear identification of the module, even after many years.

In some embodiments, the provision of the recording comprises the provision of an X-ray recording of the module. X-ray images of electronic modules have unique patterns or features, inter alia due to the joints, for example solder joints of BGA or QFN components. It has been found that the features or the combination of a plurality of such features can be used as a fingerprint of the electronic circuit. The features may be caused by the joining process.

In some embodiments, provision of the recording comprises the provision of a digital recording, in particular a digital recording in the visible spectrum, of the module. In this case, the digital recordings are in the form of optical recordings. A digital recording (e.g., a digital photograph) of the module also contains unique features. By way of example, these can be minimal deviations in the position of components themselves or of a plurality of components in relation to one another and in the position of corresponding joints. By way of example, the digital recording can be provided by a CCD camera already present on the production line.

In some embodiments, the method comprises a selection of the partial region of the recording such that the partial region includes one or more joints. It was found that joints form particularly unique patterns of features. This includes both sintered and soldered connections. The selection of a partial region is advantageous in that there is no need to further process and/or store the entire recording. The partial region may be chosen in such a way that a central component is selected. If a central component is chosen, then it may be advantageous if the component has a large joining surface in relation to its footprint, as this joining surface shows a correspondingly unique and well-evaluable pattern of features. Partial region information relating to the location of the partial region can be stored in the data set. The selection of the partial region can serve as a further safeguard against imitators if the partial region is chosen at random.

In some embodiments, the identification data set is generated on the basis of at least a number and/or an arrangement and/or a size of features in at least one of the joints. Joints have irregularities that are used in this case. These irregularities are due to gas inclusions, for example, whose shape, size, number, and distribution are unique for each joint.

In some embodiments, the identification data set is generated on the basis of gas inclusions in joints as features. It was found that the gas inclusions form particularly unique patterns, that is to say combinations of features.

In some embodiments, the generation of the identification data set comprises a combination of at least two distinct recordings. If the identification should be able to be carried out with a particularly high degree of reliability, it is possible to combine a plurality of recordings, in particular at least one x-ray recording and one digital recording, for example a recording by a CCD/CMOS camera in the visible spectrum. The recordings can be overlaid in order to obtain as many features as possible for identification.

In some embodiments, the generation of the identification data set comprises at least a calculation of a hash value of at least one partial region of the recording. In principle, it is possible to generate usual hash values of the recording, for example SHA. This hash value has the property of generating a different value already for the smallest changes in the recording. This would even be the case if a test regarding is recorded by a different recording device (different X-ray apparatus). To find similarities, a perceptual hash method that is less sensitive to small fluctuations in the recording quality and is adapted to the actual perception of the features can be recommended. Such methods are used, for example, for image searches. Well-known methods in this respect are pHash and Blockhash.io, for example.

In some embodiments, at least one serial number of the module is stored when the identification data set is generated. The serial number links further data available from the manufacturer with the identification data set. In this way, the identification data set can be assigned to additional information quickly and easily, and an initial check can already be carried out directly on the module.

In some embodiments, a quality value based on the number and/or the arrangement and/or the size of the gas inclusions is generated during the generation of the identification data set. Together with the identification data set, this quality value can later serve not only to uniquely identify the module but also to identify the conformity of the said module to quality criteria relating to a maximum number or size of the gas inclusions. The arrangement of the gas inclusions can also be decisive here (e.g., no bubbles in critical edge areas).

Some embodiments include a method for producing an electronic module, comprising: providing a substrate with joining material, equipping at least one electronic component, finishing at least one joint between the electronic component and the substrate, and generating an identification data set according to one or more of the methods described herein. Thus, these methods incorporating teachings of the present disclosure can be carried out directly during production and the identification data set can be generated. This is particularly efficient since existing inspection recordings can be used to generate the identification data set.

Some embodiments include the use of an identification data set generated using one or more of the methods described herein, as at least part of a cryptographic secret for authentication and/or encryption of a communication of an electronic module. The use of at least parts of the identification data set enables the creation of secrets for authentication and/or encryption directly during production. The security of the modules can be increased in this way.

Some embodiments include the use of an identification data set generated using one or more of the methods described herein as a physical unclonable function.

Some embodiments include a method for checking an electronic module, comprising: providing an identification data set for the module, providing a test recording of at least a partial region of the module, generating a test data set on the basis of at least a partial region of the test recording, and comparing the identification data set with the test data set.

The generation of the test data set can be analogous to the generation of the identification data set, e.g. on the basis of the same algorithm. By way of example, the test data set can therefore be generated from the test recording by applying the method for generating an identification data set. If the recordings are made directly, it is possible to carry out an identification by way of an image comparison, for example by overlaying the recordings. A difference image can also be created here using appropriate algorithms that highlight any deviations.

In some embodiments, the partial region of the test recording is selected on the basis of partial region information in the identification data set in order to check the electronic module. There can be a direct comparison of the data in this way.

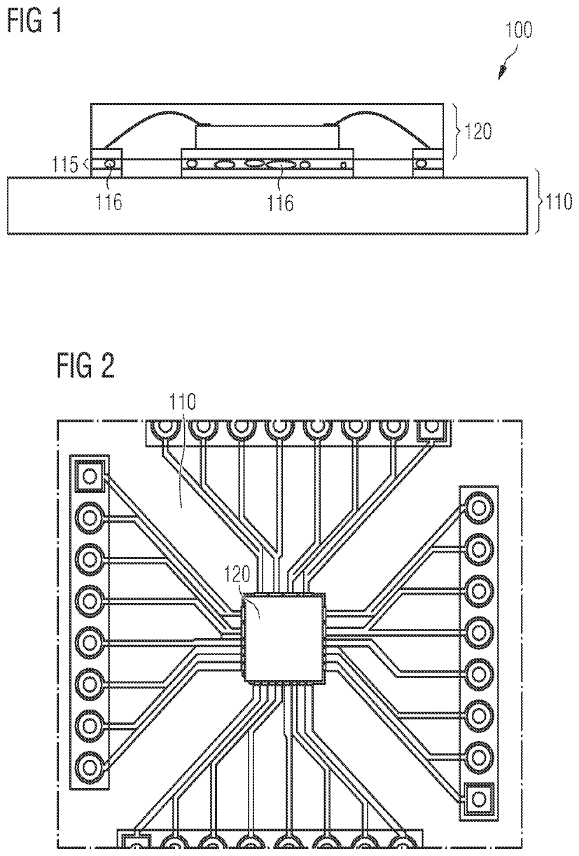

FIG. 1 shows an electronic module 100 in cross section. The module 100 comprises a substrate 110, a joint 115, and an electronic component 120, with the electronic component 120 being joined to the electronic substrate 110 by means of the joint 115. Joint 115 has relatively small gas inclusions 116 in this case. The gas inclusions 116 are unique features M115, which can be used in the further method for generating an identification data set.

FIG. 2 shows a plan view of the electronic module 100 from FIG. 1. In this case, the electronic component 120 covers the joint 115, and so the latter cannot be seen here. Nevertheless, minimal deviations in the assembly of the electronic component can serve as distinguishing features.

If an X-ray image is taken during production of a central component part, in this case the electronic component 120, and stored with the serial number of the said module, it is possible at any later stage to prove whether a module in question from the field actually corresponds to the manufactured module. It is moreover possible to determine with some certainty whether this module has been modified in terms of hardware since a corresponding (subsequent and additional) soldering process would lead to a different pattern.

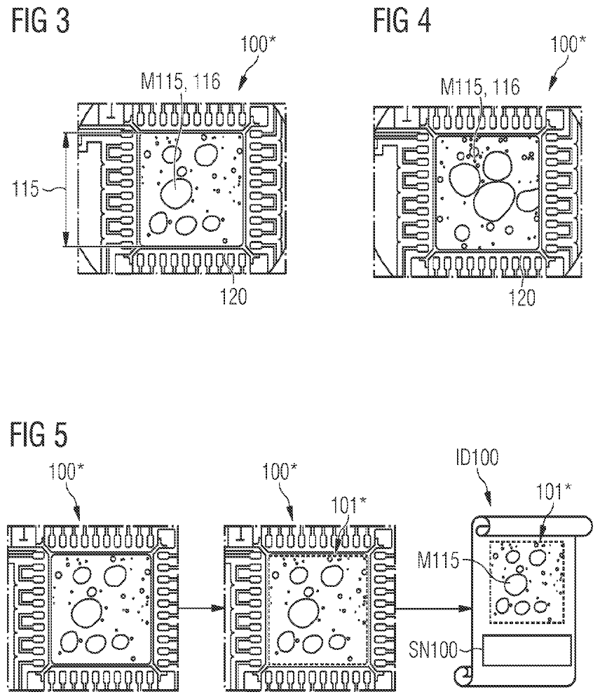

FIG. 3 shows an X-ray recording 100* of a module 100 with a component 120 but the latter is transparent since the X-ray recording 100* primarily shows the joint. Gas inclusions 116 in the joint 115 can be seen here as feature M115. The gas inclusions 116 have formed an unmistakable pattern in the process, the said pattern occurring randomly as a result of the joining process and therefore not being able to be copied.

As a comparison, FIG. 4 shows a further X-ray recording 100* with a similar component 120, which was soldered under similar process conditions. A pattern of the gas inclusions 116, which differs from component 120 in FIG. 3 to component 120 in FIG. 4, is clearly evident. By “overlaying” or simply comparing the features M115, in this case therefore the gas inclusions 116, it is already possible, merely by way of observation, to state with quite a high degree of certainty that the components 120 are not one and the same components 120 and therefore this likewise is not the same module 100. The comparison can be fully automated by the hash method described according to one embodiment of the invention.

FIG. 5 shows a recording 100* as is known from FIG. 3 and FIG. 4. A partial region 101* of the recording 100* is now selected in order to obtain a basis that is as meaningful as possible for the identification data set ID100. In the present case, the partial region that has a joining surface 115 with a meaningful pattern of features M115 is selected. In this case, the partial region 101* can be selected by the developer of the module 100. In some embodiments, an algorithm automatically selects the partial region 101* on the basis of parameters of the module 100, for example the size of joints 115 or the features M115.

In a further step, the identification data set ID100 is completed; in this case, the partial region 101* of the recording 100*, which has meaningful features M115, is stored in connection with a serial number SN100 of the module in the identification data set ID100. In an alternative embodiment, a hash value of the partial region can also be created and stored in the identification data set ID100 as an alternative or in addition to the partial region 101*.

In summary, the teachings herein include computer-implemented methods and/or systems for generating an identification data set (ID100) for an electronic module (100), the module (100) having at least one substrate (110), at least one joint (115), and at least one electronic component (120). In order to specify a simplified method for generating a secure identification data set (ID100) for electronic modules (100), an example method comprises: providing a recording (100*) of at least a partial region of the module (100), and generating the identification data set (ID100) on the basis of at least a partial region (101*) of the recording (100*).

### REFERENCE SYMBOLS

100 Electronic module
110 Substrate
115 Joint
116 Gas inclusion
120 Electronic component
100* Recording of the module
101* Partial region of the recording
M115 Feature of the joint
ID100 Identification data set
SN100 Electronic module serial number

What is claimed is:

1. A computer-implemented method for generating an identification data set for an electronic module having a substrate, a joint, and an electronic component, the method comprising:
providing a digital and/or X-ray recording of at least a partial region of the module; and
generating the identification data set based on at least a portion of the recording, the portion including the joint;
wherein the identification data set identifies at least one of a number, an arrangement, and/or a size of gas inclusions in the joint.

2. The method as claimed in claim 1, wherein generating the identification data set comprises combining at least two different methods for providing the recording.

3. The method as claimed in claim 1, wherein generating the identification data set comprises calculating a hash value of the portion of the recording.

4. The method as claimed in claim 1, wherein generating the identification data set includes storing a serial number of the module.

5. The method as claimed in claim 1, wherein generating the identification data set comprises generating a quality value based on a number and/or an arrangement and/or a size of the gas inclusions.

6. A method for producing an electronic module, the method comprising:
providing a substrate with joining material;
equipping an electronic component on the substrate;
finishing a joint between the electronic component and the substrate to create a modulo; and
providing a digital and/or X-ray recording of at least a partial region of the module, the partial region including the joint; and
generating the identification data set based on at least a portion of the recording including the joint;
wherein the identification data set identifies at least one of a number, an arrangement, and/or a size of gas inclusions in the joint.

7-8. (canceled)

9. A method for checking an electronic module, the method comprising:
providing a digital and/or X-ray recording of at least a partial region of the module, the partial region including a joint between a substrate and an electronic component;
generating an identification data set based on at least a portion of the recording including the joint;
wherein the identification data set identifies at least one of a number, an arrangement, and/or a size of gas inclusions in the joint;
providing a test recording of at least a partial region of the module;
generating a test data set on the basis of at least a partial region of the test recording; and
comparing the identification data set with the test data set.

10. The method as claimed in claim 9, further comprising selecting the partial region of the test recording based on partial region information in the identification data set.
